(19) United States
(12) Patent Application Publication
(10) Pub. No.: US 2026/0348540 A1
(43) Pub. Date: Nov. 5, 2026

(54) LED LIGHT STRIP STRUCTURE

(71) Applicant: JIANGXI YSING LIGHTING TECHNOLOGY CO., LTD, Pingxiang (CN)

(72) Inventor: MINGJIAN LIU, Dongguan (CN)

(21) Appl. No.: 19/712,044

(22) Filed: Jun. 18, 2026

Related U.S. Application Data
(63) Continuation of application No. PCT/CN2024/134998, filed on Nov. 27, 2024.

(30) Foreign Application Priority Data
Jan. 10, 2024 (CN) 2024200629845

(51) Int. Cl. F21S 4/24; F21V 3/06; F21V 15/015; F21V 23/00; F21V 31/04; F21Y 105/16; F21Y 113/17; F21Y 115/10; H10H 29/24; H10H 29/80; H10H 29/85; H10H 29/854

(52) U.S. Cl. CPC F21S 4/24; F21V 3/062; F21V 15/015; F21V 23/002; F21V 23/005; F21V 31/04; H10H 29/24; H10H 29/854; H10H 29/857; H10H 29/922; H10H 29/942; F21Y 2105/16; F21Y 2113/17; F21Y 2115/10

(57) ABSTRACT

An LED light strip structure includes a light strip, end caps, and an encapsulating body. The encapsulating body covers an outer side of the light strip, and the end caps are disposed at two ends of the encapsulating body. The encapsulating body at least includes a light-transmissive encapsulant and a light-blocking encapsulant. The light strip has a light-emitting surface of the light strip, a backlight surface of the light strip, and two side surfaces of the light strip. The light-blocking encapsulant wraps outer sides of the two side surfaces of the light strip and extends in a length direction of the light strip. The light-transmissive encapsulant is disposed on the light-emitting surface of the light strip and the backlight surface of the light strip.

This application is a National Stage Entry of International Application No. PCT/CN 2024/134998, filed on Nov. 27, 2024, which claims priority to Chinese Patent Application No. 2024200629845, entitled “LED Light Strip Structure”, filed on Jan. 10, 2024, which is incorporated herein by reference.

### TECHNICAL FIELD

The present application relates to the field of LED technology, and in particular, to an LED light strip structure.

### BACKGROUND

The light-emitting diodes (LEDs) have been widely utilized in the lighting and display industries due to their advantages including energy efficiency, high efficacy, fast response time, long service life, mercury-free composition and environmental friendliness, so that LEDs have become one of the most prominent products in recent years.

As a typical application of LEDs, a light-emitting diode (LED) light strip generally includes a light strip and a transparent adhesive layer injection-molded and wrapped around the light strip. Light emitted by the light strip radiates outward in all directions through the transparent adhesive layer, resulting in light leakage, low light utilization efficiency and severe light pollution, which fail to meet lighting requirements.

### SUMMARY OF THE INVENTION

The present application provides an LED light strip structure. The LED light strip structure allows light of the light strip to be emitted in a single direction toward the light-transmissive encapsulant disposed on the light-emitting surface of the light strip, which can prevent problems such as light leakage or light pollution caused by scattered light emission in all directions.

The present application provides an LED light strip structure including a light strip, end caps, and an encapsulating body. The light strip has a plurality of LEDs arranged at equal intervals. The encapsulating body covers an outer side of the light strip and extends in a length direction of the light strip. Two ends of the light strip are respectively provided with an input end and an output end. The end caps are disposed at two ends of the encapsulating body, and the end caps exert a damping force to the input end and the output end to prevent the input end and the output end from sliding relative to the light strip.

The encapsulating body at least includes a light-transmissive encapsulant and a light-blocking encapsulant. The light strip has a light-emitting surface of the light strip, a backlight surface of the light strip, and two side surfaces of the light strip. The light-blocking encapsulant wraps outer sides of the two side surfaces of the light strip and extends in the length direction of the light strip. The light-transmissive encapsulant is disposed on the light-emitting surface of the light strip and/or the backlight surface of the light strip.

The beneficial effects of the present application may be as follows. An LED light strip structure of the present application includes a light strip, end caps, and an encapsulating body. The encapsulating body at least includes a light-transmissive encapsulant and a light-blocking encapsulant. The light-blocking encapsulant wraps outer sides of two side surfaces of the light strip and extends in the length direction of the light strip. The light-transmissive encapsulant is disposed on the light-emitting surface of the light strip, so that light of the light strip is emitted in a single direction toward the light-transmissive encapsulant disposed on the light-emitting surface of the light strip, and problems such as light leakage or light pollution caused by scattered light emission in all directions are prevented. In addition, the light-transmissive encapsulant may also be disposed on the backlight surface of the light strip, so that light strip information on the light strip can be displayed through the light-transmissive encapsulant; the light strip information includes an operating voltage of the light strip, a cutting position of the light strip, and the like. Moreover, the end caps are disposed at two ends of the encapsulating body, and may exert a damping force to the input end and the output end to prevent the input end and the output end from sliding relative to the light strip, and avoiding breakage of metal cables of the input end and the output.

It should be understood that both the foregoing general description and the following detailed description are exemplary and explanatory and are not restrictive of the present application.

### BRIEF DESCRIPTION OF THE DRAWINGS

To describe technical solutions of embodiments of the present application more clearly, the following briefly describes accompanying drawings used in the description of the embodiments. The accompanying drawings in the following description show some embodiments of the present application, and a person of ordinary skill in the art may still derive other drawings from these accompanying drawings without undue experimentation.

FIG. 1 is a schematic structural diagram of an LED light strip structure according to an embodiment of the present application;

FIG. 2 is an exploded schematic diagram of the LED light strip structure in FIG. 1;

FIG. 3 is a schematic structural diagram of an end cap in FIG. 1;

FIG. 4 is a partial structural diagram of the LED light strip structure in FIG. 1;

FIG. 5 is a partial structural diagram of the LED light strip structure in FIG. 1 from another angle;

FIG. 6 is a partial exploded view of the LED light strip structure in FIG. 1;

FIG. 7 is a first schematic structural diagram of an LED in FIG. 1;

FIG. 8 is an exploded schematic diagram of the LED in FIG. 7;

FIG. 9 is an exploded schematic diagram of the LED in FIG. 8;

FIG. 10 is a second schematic structural diagram of the LED in FIG. 1;

FIG. 11 is a third schematic structural diagram of the LED in FIG. 1;

FIG. 12 is a fourth schematic structural diagram of the LED in FIG. 1;

FIG. 13 is a fifth schematic structural diagram of the LED in FIG. 1.

### REFERENCE NUMERALS

100, Light strip; 101, LED; 102, Circuit board; 200, Encapsulating body; 201, Light-blocking encapsulant; 202, Light-transmissive encapsulant; 300, End cap; 301, Strain relief structure; 400, Input end; 500, Output end;

10, Light-emitting assembly; 11, Driving chip; 12, Light-emitting chip group; 121, Red chip; 122, Blue chip; 123, Green chip;

20, Conductive pin; 20a, Via structure; 20b, Accommodating area; 21, Ground pin; 211, First die-bonding portion; 2111, Second extending portion; 212, First soldering portion; 22, Power pin; 221, Second die-bonding portion; 2211, Third extending portion; 2212, Fourth extending portion; 2213, Fifth extending portion; 222, Second soldering portion; 23, Signal input pin; 231, Third die-bonding portion; 232, Third soldering portion; 24, Signal output pin; 241, Fourth die-bonding portion; 242, Fourth soldering portion; 25, Transition pin; 251, Transition die-bonding portion; 2511, First transition die-bonding portion; 2512, Second transition die-bonding portion; 2513, Third transition die-bonding portion;

30, Insulating base; 31, First end surface;

40, Encapsulating compound.

### DETAILED DESCRIPTION

The following clearly and completely describes the technical solutions in the embodiments of the present application with reference to the accompanying drawings in the embodiments of the present application. The described embodiments are some of the embodiments of the present application, rather than all of the embodiments. Based on the embodiments in the present application, all other embodiments obtained by a person of ordinary skill in the art without undue experimentation fall within the protection scope of the present application.

It should also be understood that the terms used in the description of the present application are merely for the purpose of describing embodiments. In the description of the present application, it should be understood that orientation or positional relationships indicated by terms such as “center”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise” are based on the orientation or positional relationships shown in the accompanying drawings, are merely for convenience of describing the present application and simplifying the description, and do not indicate or imply that the apparatus or component referred to must have an orientation or be constructed and operated in a n orientation, and therefore cannot be construed as a limitation on the present application. In addition, terms “first” and “second” are used for descriptive purposes and are not to be construed as indicating or implying relative importance or implicitly indicating the number of indicated technical features. Therefore, features defined with “first” and “second” may explicitly or implicitly include one or more of the features. In the description of the present application, “a plurality of” means two or more.

Some embodiments of the present application are described in detail below with reference to the accompanying drawings. The following embodiments and features in the embodiments may be combined with each other without conflict.

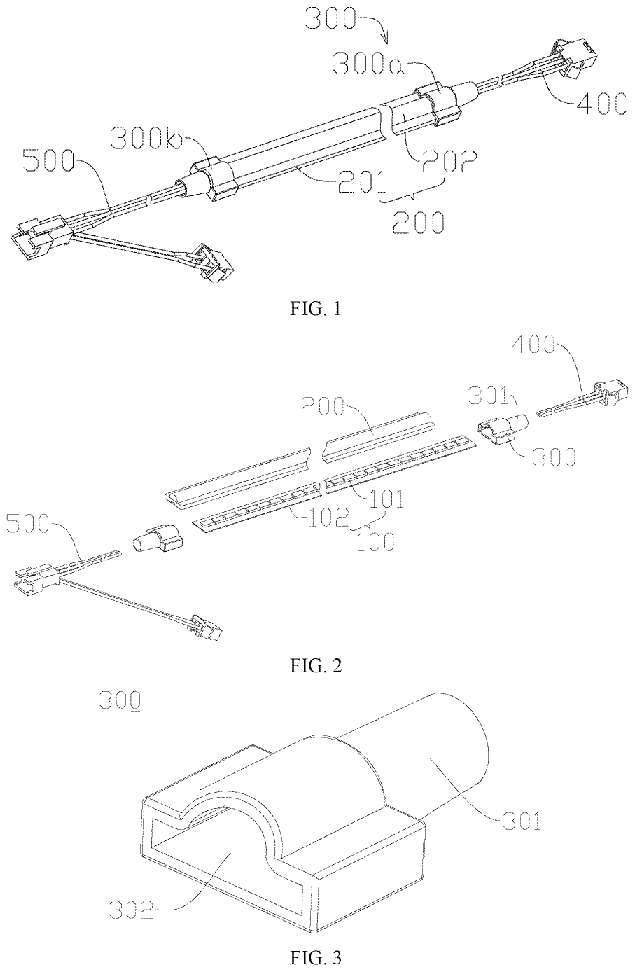

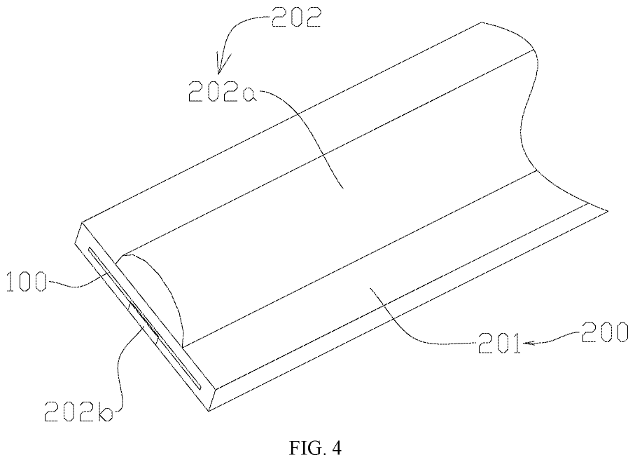

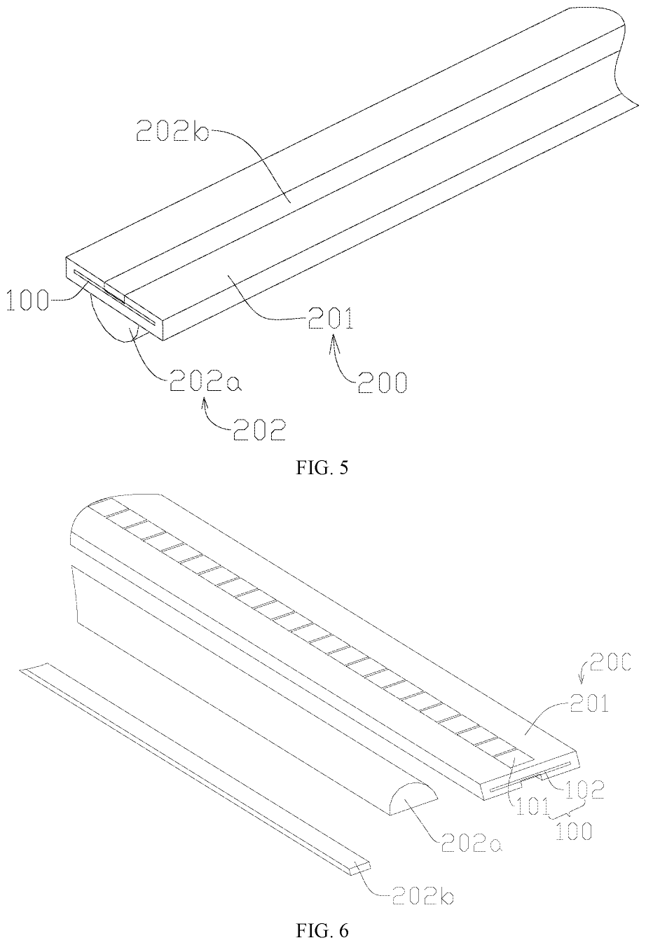

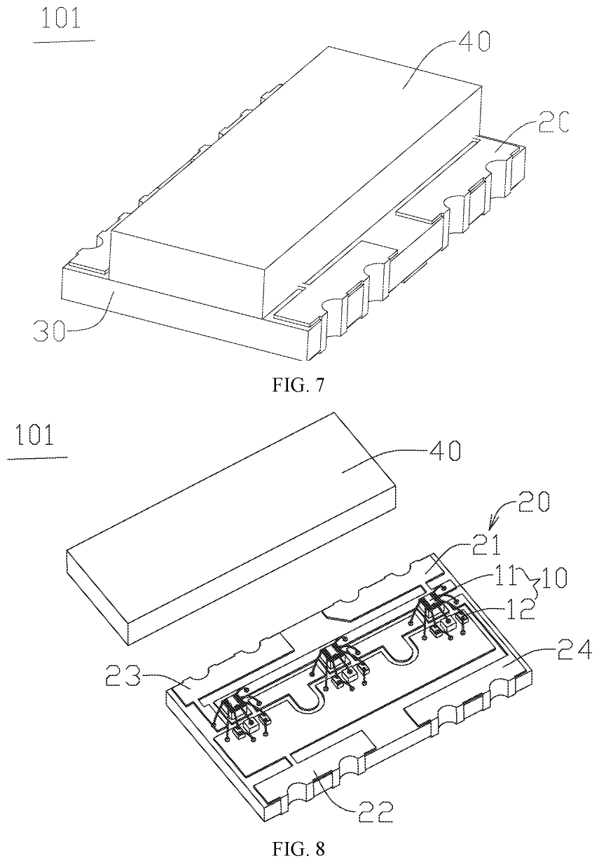

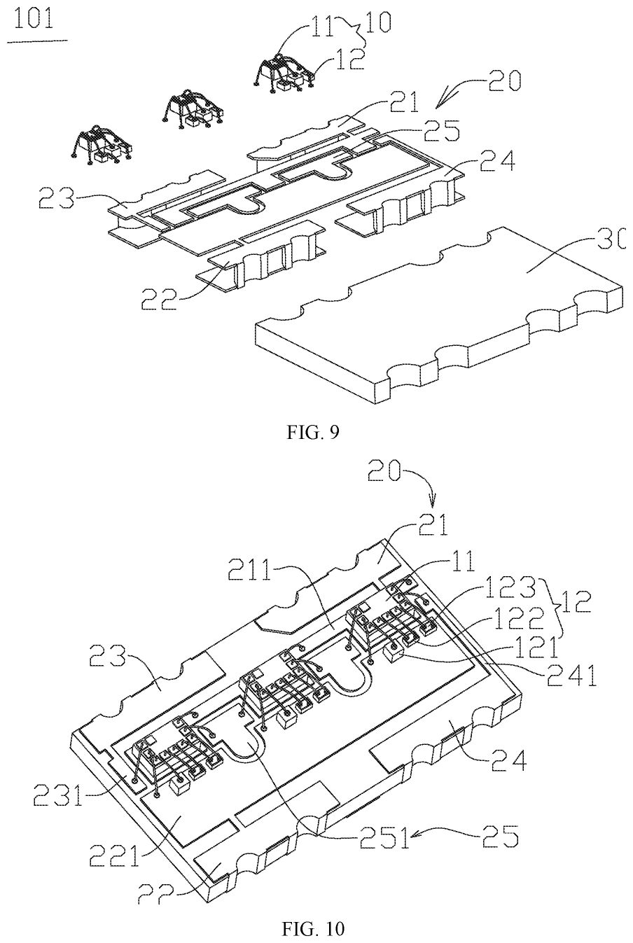

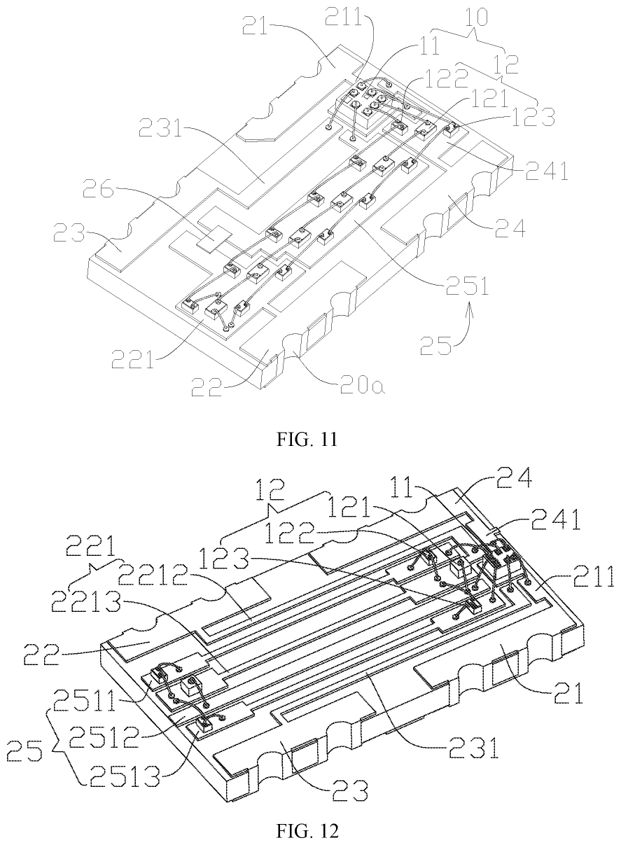

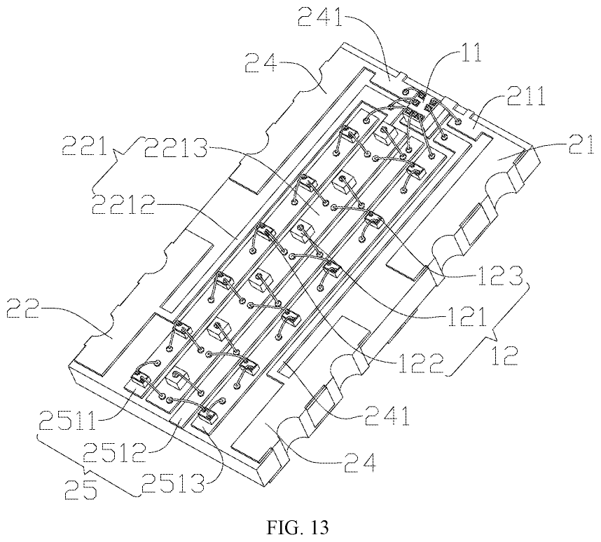

As shown in FIG. 1 to FIG. 13, the present application provides an LED light strip structure including a light strip 100, end caps 300, and an encapsulating body 200. The encapsulating body 200 covers an outer side of the light strip 100 and extends in a length direction of the light strip 100. Two ends of the light strip 100 are respectively provided with an input end 400 and an output end 500. The end caps 300 are disposed at two ends of the encapsulating body 200, and the end caps 300 a exert a certain damping force to the input end 400 and the output end 500 to prevent the input end 400 and the output end 500 from sliding relative to the light strip. This not only prevents metal pads on the light strip 100 from being pulled off during assembly and use of the input end 400, the output end 500, and the light strip 100 and prevents a short circuit inside the light strip 100, but also improves bending life of the input end 400 and the output end 500. In addition, the input end 400 and the output end 500 may deform when pulled to offset an impact on the encapsulating body 200.

In some embodiments, the input end 400 includes an input interface and an input cable, and the output end 500 includes an output interface and an output cable. An end of each end cap 300 away from the light strip 100 is provided with a strain relief structure 301. The input interface is connected to the light strip 100 through the input cable, and the output interface is connected to the light strip 100 through the output cable. The strain relief structure 301 may exert a certain damping force to the input cable and the output cable to prevent the input cable and the output cable from sliding relative to the light strip 100, and also improve bending life of the input cable and the output cable. When the input cable or the output cable is bent, the strain relief structure 301 deforms first to protect the input cable or the output cable inside the strain relief structure 301 to a certain extent, and the strain relief structure itself does not crack or break, which effectively protects a connection between the light strip 100 and the input cable and the output cable from cracking of a cable sheath and breakage of a cable core during bending.

In some embodiments, the end caps 300 include a first end cap 300a and a second end cap 300b. The first end cap 300a is disposed at a connection between the input cable and the light strip 100, and the second end cap 300b is disposed at a connection between the output cable and the light strip 100. An end of each of the first end cap 300a and the second end cap 300b facing away from the strain relief structure 301 is formed with an accommodating groove 302 for accommodating the light strip 100 or wrapping an outer side of the light strip 100, so that the light strip 100 can form an integrated structure with the first end cap 300a and the second end cap 300b.

In some embodiments, the encapsulating body 200 at least includes a light-transmissive encapsulant 202 and a light-blocking encapsulant 201. The light strip 100 has a light-emitting surface of the light strip, a backlight surface of the light strip, and two side surfaces of the light strip. The light-blocking encapsulant 201 wraps outer sides of the two side surfaces of the light strip and extends in the length direction of the light strip 100. The light-transmissive encapsulant 202 is disposed on the light-emitting surface of the light strip and/or the backlight surface of the light strip, so that light of the light strip 100 is emitted in a single direction toward the light-transmissive encapsulant disposed on the light-emitting surface of the light strip, and problems such as light leakage or light pollution caused by scattered light emission in all directions are prevented. In addition, when the light-transmissive encapsulant 202 is disposed on the backlight surface of the light strip, light strip information engraved on the backlight surface of the light strip can be displayed through the light-transmissive encapsulant. The light strip information includes, but is not limited to, an operating voltage of the light strip, a cutting position of the light strip, and the like, so as to prevent the LED beads on the light strip 100 from being cut when a user cuts the light strip. The operation is simple and convenient, meets industrial requirements, and is suitable for popularization and use.

In some embodiments, the light strip 100 includes a circuit board 102 and a plurality of LEDs 101. The plurality of LEDs 101 are arranged at equal intervals in the length direction of the circuit board 102. The light-blocking encapsulant 201 wraps two side surfaces of the circuit board 102 and extends in the length direction of the circuit board 102. The light-transmissive encapsulant 202 is disposed on a front surface of the circuit board 102 and located outside the LEDs 101, so that light emitted by the LEDs 101 is emitted along a front surface of the light-transmissive encapsulant 202. In addition, the light-transmissive encapsulant 202 is disposed on a back surface of the circuit board 102, so that light strip information engraved on the circuit board 102 of the light strip can be displayed through the light-transmissive encapsulant. If the light strip information is engraved on the light-blocking encapsulant 201, it is not convenient for the user to quickly identify the light strip information, and it is difficult to determine the cutting position of the light strip 100, which may result in accidental cutting of the LED beads on the light strip 100.

In some embodiments, the light-blocking encapsulant 201 is integrally formed with the light strip 100, a first long groove is formed at the light-emitting surface of the light strip 100. The light-transmissive encapsulant 202 is disposed in the first long groove, so that light emitted by the LEDs 101 can be emitted from the light-transmissive encapsulant 201 in the first long groove. This improves light utilization efficiency and prevents light pollution, and the LED light strip structure has excellent market promotion value. The light-blocking encapsulant 201 and the light strip 100 may be integrally formed through an extrusion process.

A depth of the first long groove is not less than 0. When the depth of the first long groove is 0, the light-emitting surface of each LED 101 is exactly flush with an end surface of the light-blocking encapsulant 201, or at least part of the light-emitting surface of each LED 101 is exposed out of the light-blocking encapsulant 201. The light-transmissive encapsulant 202 may be attached to the light-emitting surface of each LED 101, or the light-transmissive encapsulant 202 may be attached to the light-blocking encapsulant 201 and located outside the LEDs 101. That is, the first long groove may be a marker formed at a position of the LEDs 101 after the light-blocking encapsulant 201 and the light strip 100 are integrally injection-molded. The plurality of LEDs 101 are arranged at equal intervals in the length direction of the circuit board 102, so that the marker forms a long groove structure extending in the length direction.

In some embodiments, a second long groove is formed in the light-blocking encapsulant 201 at the backlight surface of the light strip 100. The light-transmissive encapsulant 202 is disposed in the second long groove, so that light strip information on the backlight surface of the light strip can be displayed through the light-transmissive encapsulant 202. The light strip information may be disposed on the backlight surface of the light strip by means of printing, code spraying, engraving, or the like, which is not limited in the present application. In some embodiments, the light-transmissive encapsulant 202 includes a light-transmitting strip 202a made of fully transparent silica gel or translucent silica gel. The light-transmitting strip 202a is formed outside the light-emitting surface of the light strip and is in a 3D arc shape. Light is transmitted outward through the arc-shaped light-transmitting strip 202a, so that a light-emitting effect of not less than 180 degrees can be provided. The light-transmissive encapsulant 202 further includes an identification strip 202b made of fully transparent silica gel or translucent silica gel. The identification strip 202b fills the second long groove and is flush with an end surface of the light-blocking encapsulant 201, so that light strip information engraved on the backlight surface of the light strip can be displayed through the identification strip 202b. Meanwhile, the light-blocking encapsulant 201 and the identification strip 202b can be attached to a mounting surface to fix and mount the light strip structure.

In some embodiments, the light-blocking encapsulant 201 and the light-transmissive encapsulant 202 are made of a silica gel material or a PU material, which facilitates bending of the light strip structure, prevents breakage, and has anti-freezing and sun-proof effects. In addition, wrapping the LED beads with the light-transmissive encapsulant 202 made of silica gel or PU adhesive provides an ultra-bright light-emitting effect without dark areas and particles.

In some embodiments, each LED 101 includes a light-emitting assembly 10, an insulating base 30, an encapsulating compound 40, and a plurality of conductive pins 20. The plurality of conductive pins 20 are disposed on the insulating base 30. The light-emitting assembly 10 is disposed on the conductive pins 20 and electrically connected to the conductive pins 20. The encapsulating compound 40 encloses the light-emitting assembly 10, which not only protects the light-emitting assembly 10 but also improves light transmission effect of the light-emitting assembly 10.

The light-emitting assembly 10 includes a driving chip 11 and a plurality of light-emitting chip groups 12 combined in parallel or in series. The plurality of light-emitting chip groups 12 are arranged sequentially in a layout direction of the insulating base 30. A spacing between two adjacent light-emitting chip groups 12 corresponds to a spacing between two adjacent LEDs 101. The at least one driving chip 11 is electrically connected to the plurality of light-emitting chip groups 12 to drive the plurality of light-emitting chip groups 12 to emit light. The layout direction may be, but is not limited to, a length direction and a width direction of the insulating base 30. Meanwhile, the spacing between adjacent light-emitting chip groups 12 is determined by the spacing between two adjacent LEDs 101. That is, before packaging of the LED 101, the spacing between two adjacent light-emitting chip groups 12 in the LED 101 is determined according to the spacing between two adjacent LEDs 101 on the light strip 100. The two LEDs 101 have a minimum physical size due to limitations of pads and packaging processes. Therefore, in the present application, the plurality of light-emitting chip groups 12 are integrated into one LED 101, which meets requirements of the minimum size between two adjacent LEDs 101. A distance between adjacent light-emitting chip groups 12 in the LED 101 can be made infinitely small. However, to meet light emission uniformity of the light strip 100, the spacing between two adjacent light-emitting chip groups 12 in the LED 101 is equal to the spacing between two adjacent LEDs 101 on the light strip 100. That is, when the spacing between two adjacent LEDs 101 meets the minimum physical size, the distance between adjacent light-emitting chip groups 12 in the LED 101 can also meet the minimum physical size. In some embodiments, each light-emitting chip group 12 includes a blue chip 122, a green chip 123, and a red chip 121. The driving chip 11 is electrically connected to the blue chip 122, the green chip 123, and the red chip 121 to drive the blue chip 122, the green chip 123, and the red chip 121 to emit light.

In some embodiments, the number of light-emitting chip groups 12 is three, so that the number of blue chips 122 is three, the number of green chips 123 is three, and the number of red chips 121 is three. The three blue chips 122 may be combined in series or in parallel. The three green chips 123 may be combined in series or in parallel. The three red chips 121 may be combined in series or in parallel. In addition, the blue chips 122, the green chips 123, and the red chips 121 may be combined in series or in parallel. The number of driving chips 11 may be one or more, which is not limited in the present application.

After adopting the above technical solutions, a plurality of blue chips 122, a plurality of green chips 123, and a plurality of red chips 121 are integrated into the LED at equal intervals, which enables the plurality of blue chips 122, the plurality of green chips 123, and the plurality of red chips 121 in one LED to emit corresponding light to produce diverse light colors and simulate a color flickering effect. The LEDs can be connected in series or in parallel according to requirements, and different driving voltages can be set, so as to realize high-density small-pitch design of LED products, improve color effect and display effect of LED products, and make resolution of LED products more delicate.

In some embodiments, the insulating base 30 has a first end surface 31. The conductive pins 20 have die-bonding portions formed on the first end surface 31. The driving chip 11, the blue chip 122, the green chip 123, and the red chip 121 are disposed on the die-bonding portions and electrically connected to the die-bonding portions. The encapsulating compound 40 encloses the die-bonding portions.

In some embodiments, the conductive pins 20 further include soldering portions. The soldering portions are formed on other end surfaces of the insulating base 30. A via structure 20a is provided in a partial region of the soldering portions to enhance welding strength of a product, so that the via structure 20a can accommodate part of a soldering material.

After adopting the above technical solutions, since the soldering portions are formed on end surfaces of the insulating base 30 other than the first end surface 31, heat dissipation effect of the LED can be effectively improved, and a welding area and welding firmness of the soldering portions can be increased.

A size of each die-bonding portion is determined according to the number of the plurality of light-emitting chip groups 12 and a spacing between the plurality of light-emitting chips. Therefore, integrating the plurality of light-emitting chip groups 12 on the die-bonding portions in the present application not only improves heat dissipation effect of the light-emitting chips but also ensures light-emitting effect of the LED, and can be applied to various light homogenization scenarios.

In some embodiments, the conductive pins 20 include a power pin 22 and a ground pin 21. The driving chip 11 is electrically connected to the power pin 22 and the ground pin 21. The blue chip 122, the green chip 123, and the red chip 121 are electrically connected to the power pin 22 and the driving chip 11. The blue chip 122, the green chip 123, and the red chip 121 are arranged on the insulating base 30 at equal intervals to realize high-density small-pitch design of the LED.

In some embodiments, the driving chip 11 is disposed on at least one of the power pin 22 and the ground pin 21. The light-emitting chip groups 12 may be disposed on the power pin 22, the ground pin 21, or other conductive pins 20.

In some embodiments, the light-emitting chip groups 12 are disposed on at least one of the power pin 22 and the ground pin 21. The driving chip 11 may be disposed on the power pin 22, the ground pin 21, or other conductive pins 20.

In some embodiments, the driving chip 11 is disposed on the ground pin 21, and the light-emitting chip groups 12 are disposed on the power pin 22.

In some embodiments, a second input end of the driving chip 11 is electrically connected to the ground pin 21. First input ends of the driving chip 11 and the light-emitting chip groups 12 are electrically connected to the power pin 22. A second input end of each light-emitting chip group 12 is connected to the driving chip 11. That is, the light-emitting chips in each light-emitting chip group 12 are combined in parallel and can also be controlled to emit light through the driving chip 11.

In other embodiments, a first input end of the driving chip 11 is electrically connected to the power pin 22, and a second input end of the driving chip 11 is electrically connected to the ground pin 21. A first input end and a second input end of each light-emitting chip group 12 are connected to the driving chip 11. That is, the light-emitting chips of each light-emitting chip group 12 are combined in series and obtain an operating voltage through the driving chip 11, and can also be controlled to emit light through the driving chip 11.

In some embodiments, the number of driving chips 11 and the number of light-emitting chip groups 12 are both three, so that the number of blue chips 122 is three, the number of green chips 123 is three, and the number of red chips 121 is three. The three blue chips 122, the three green chips 123, and the three red chips 121 are correspondingly connected to the three driving chips 11 to form three light-emitting groups. That is, each driving chip 11 can control one blue chip 122, one green chip 123, and one red chip 121. Meanwhile, the blue chip 122, the green chip 123, and the red chip 121 are combined in parallel, and the three light-emitting groups are arranged in parallel at equal intervals.

In some embodiments, the number of driving chips 11 and the number of light-emitting chip groups 12 are both four, so that the number of blue chips 122 is four, the number of green chips 123 is four, and the number of red chips 121 is four. The four blue chips 122, the four green chips 123, and the four red chips 121 are correspondingly connected to the four driving chips 11 to form four light-emitting groups. That is, each driving chip 11 can control one blue chip 122, one green chip 123, and one red chip 121. Meanwhile, the blue chip 122, the green chip 123, and the red chip 121 are combined in parallel, and the four light-emitting groups are arranged in parallel at equal intervals.

In some embodiments, the number of driving chips 11 and the number of light-emitting chip groups 12 are both three, so that the number of blue chips 122 is three, the number of green chips 123 is three, and the number of red chips 121 is three. The three blue chips 122, the three green chips 123, and the three red chips 121 are correspondingly connected to the three driving chips 11 to form three light-emitting groups. That is, each driving chip 11 can control one blue chip 122, one green chip 123, and one red chip 121. Meanwhile, the blue chip 122, the green chip 123, and the red chip 121 are combined in series through the driving chip 11, and the three light-emitting groups are arranged in parallel at equal intervals.

In some embodiments, the number of driving chips 11 is one, and the number of light-emitting chip groups 12 is at least two, so that the number of blue chips 122 is at least two, the number of green chips 123 is at least two, and the number of red chips 121 is at least two. At least two blue chips 122 are combined in series to form a first light-emitting group. At least two red chips 121 are combined in series to form a second light-emitting group. At least two green chips 123 are combined in series to form a third light-emitting group. The first light-emitting group, the second light-emitting group, and the third light-emitting group are combined in parallel and electrically connected to the driving chip 11, so that the driving chip 11 can control light emission of the first light-emitting group, the second light-emitting group, and the third light-emitting group.

In some embodiments, the number of driving chips 11 is one, and the number of light-emitting chip groups 12 is two, so that the number of blue chips 122 is two, the number of green chips 123 is two, and the number of red chips 121 is two. One blue chip 122, one green chip 123, and one red chip 121 are located on one side of the insulating base 30 in the length direction. The other blue chip 122, the other green chip 123, and the other red chip 121 are located on the other side of the insulating base 30 in the length direction. The driving chip 11 is disposed on one side of the insulating base 30 in the length direction and electrically connected to the blue chips 122, the green chips 123, and the red chips 121 to control light emission of the two blue chips 122, the two green chips 123, and the two red chips 121.

In some embodiments, the LED is formed by a CHIP packaging technology. That is, a corresponding circuit is laid on a packaging substrate first, then the driving chip 11 and the light-emitting chip groups 12 are arranged at equal intervals, and finally electrical connection is performed.

In some embodiments, the ground pin 21 includes a first soldering portion 212 and a first die-bonding portion 211. The power pin 22 includes a second soldering portion 222 and a second die-bonding portion 221. Part of the second soldering portion 222 and part of the first soldering portion 212 are disposed on two opposite sides of the insulating base 30. The driving chip 11 is disposed on the first die-bonding portion 211, and the light-emitting chip groups 12 are disposed on the second die-bonding portion 221. In this embodiment, a size of the first die-bonding portion 211 corresponds to the number and density of the first die-bonding portions 211, and a size of the second die-bonding portion 221 corresponds to the number and density of the light-emitting chip groups 12. So that heat generated during operation of the driving chip 11 and the light-emitting chip groups 12 can be transferred to the first soldering portion 212 and the second soldering portion 222 through the first die-bonding portion 211 and the second die-bonding portion 221 respectively, and then transferred to a circuit board connected thereto or diffused to an external environment through the first soldering portion 212 and the second soldering portion 222.

In some embodiments, the conductive pins 20 further include a signal input pin 23 and a signal output pin 24. The signal input pin 23 and the signal output pin 24 are electrically connected to a signal input end and a signal output end of the driving chip 11 respectively. Alternatively, a signal input end of one driving chip 11 is electrically connected to a signal output end of an adjacent driving chip 11. The signal input pin 23 is electrically connected to the signal input end of the driving chip 11 on one side of the insulating base 30, and the signal output pin 24 is electrically connected to the signal output end of the driving chip 11 on the other side of the insulating base 30. So that the signal input pin 23 and the signal output pin 24 can input or output control signals of the light-emitting chip groups 12 to the driving chip 11.

In some embodiments, the signal input pin 23 and the ground pin 21 are disposed on one side of the insulating base 30, and the signal output pin 24 and the power pin 22 are disposed on the other side of the insulating base 30 opposite to the side where the signal input pin 23 and the ground pin 21 are located. This improves heat dissipation effect of the ground pin 21 and the power pin 22 during operation.

In some embodiments, the signal input pin 23 includes a third soldering portion 232 and a third die-bonding portion 231. The signal output pin 24 includes a fourth soldering portion 242 and a fourth die-bonding portion 241. Part of the third soldering portion 232 is disposed on a side adjacent to the first soldering portion 212 and on a side opposite to the second soldering portion 222. Part of the fourth soldering portion 242 is disposed on a side adjacent to the second soldering portion 222 and on a side opposite to the first soldering portion 212. The third die-bonding portion 231 is connected to the third soldering portion 232 and located on one side of the first die-bonding portion 211. The fourth die-bonding portion 241 is connected to the fourth soldering portion 242 and located on one side of the second die-bonding portion 221. The signal input ends and the signal output ends between the driving chips 11 on two sides of the insulating base 30 are electrically connected to the third die-bonding portion 231 and the fourth die-bonding portion 241 respectively.

In some embodiments, the number of driving chips 11 and the number of light-emitting chip groups 12 are at least two. The at least two light-emitting chip groups 12 are correspondingly connected to the at least two driving chips 11 and combined in parallel, so that each driving chip 11 can correspondingly control light emission of each light-emitting chip group 12 connected thereto.

In some embodiments, the conductive pins 20 further include at least one transition pin 25. The transition pin 25 has a transition die-bonding portion 251. The transition die-bonding portion 251 is disposed between two adjacent driving chips 11 and electrically connects a signal input end of one driving chip 11 to a signal output end of the other driving chip 11, which reduces a connection length of bonding wires on the driving chip 11, lowers packaging difficulty of the LED, and also simplifies a structure of the LED.

In some embodiments, the second die-bonding portion 221 and the fourth die-bonding portion 241 are disposed on two sides of the second die-bonding portion 221 and the first die-bonding portion 211. The transition die-bonding portion 251 is disposed between the second die-bonding portion 221 and the first die-bonding portion 211.

In some embodiments, the first die-bonding portion 211 has a first extending portion and at least one second extending portion 2111 perpendicular to the first extending portion. The first extending portion and the second die-bonding portion 221 extend in the length direction of the insulating base 30. The second extending portion 2111 extends toward the second die-bonding portion 221, and an accommodating area 20b is formed on the second extending portion 2111. The transition die-bonding portion 251 is disposed in the accommodating area 20b, so that the signal input end and the signal output end between two adjacent driving chips 11 can be electrically connected through the transition die-bonding portion 251, which reduces a length of bonding wires and prevents the bonding wires from breaking during packaging. In addition, the signal input end and the signal output end between two adjacent driving chips 11 may also be directly electrically connected through bonding wires, which is not limited in the present application.

In some embodiments, the number of driving chips 11 and the number of light-emitting chip groups 12 are three, and the driving chips 11 and the light-emitting chip groups 12 are arranged at equal intervals in the length direction of the insulating base 30. The driving chip 11 is disposed on the second extending portion 2111, and the transition die-bonding portion 251 is disposed between two adjacent second extending portions 2111.

In some embodiments, the second die-bonding portion 221 has a third extending portion 2211 extending toward the first extending portion. The third extending portion 2211 is disposed adjacent to the second extending portion 2111. A first input end of the driving chip 11 is connected to the third extending portion 2211 through a bonding wire. The transition die-bonding portion 251 is disposed in the accommodating area 20b formed between the third extending portion 2211 and the second extending portion 2111.

In some embodiments, the number of driving chips 11 and the number of light-emitting chip groups 12 are four, and the driving chips 11 and the light-emitting chip groups 12 are arranged at equal intervals in the length direction of the insulating base 30. The driving chip 11 is disposed on the second extending portion 2111, and the transition die-bonding portion 251 is disposed between the third extending portion 2211 and the second extending portion 2111.

In some embodiments, the number of driving chips 11 and the number of light-emitting chip groups 12 are at least two. The at least two light-emitting chip groups 12 are correspondingly connected to the at least two driving chips 11 and combined in parallel. The blue chip 122, the green chip 123, and the red chip 121 on each light-emitting chip group 12 are connected to the driving chip 11 in series.

In some embodiments, the number of driving chips 11 and the number of light-emitting chip groups 12 are three, so that the number of blue chips 122 is three, the number of green chips 123 is three, and the number of red chips 121 is three. The three blue chips 122, the three green chips 123, and the three red chips 121 are correspondingly connected to the three driving chips 11 to form three light-emitting groups. That is, each driving chip 11 can control one blue chip 122, one green chip 123, and one red chip 121. Meanwhile, the blue chip 122, the green chip 123, and the red chip 121 are combined in series through the driving chip 11. That is, two ends of the light-emitting group including the blue chip 122, the green chip 123, and the red chip 121 are electrically connected to the driving chip 11, and the three light-emitting groups are arranged in parallel at equal intervals.

In some embodiments, the number of driving chips 11 and the number of light-emitting chip groups 12 are six, so that the number of blue chips 122 is six, the number of green chips 123 is six, and the number of red chips 121 is six. The six blue chips 122, the six green chips 123, and the six red chips 121 are correspondingly connected to the six driving chips 11 to form six light-emitting groups. That is, each driving chip 11 can control one blue chip 122, one green chip 123, and one red chip 121. Meanwhile, the blue chip 122, the green chip 123, and the red chip 121 are combined in parallel. A signal input end and a signal output end between two adjacent driving chips 11 of the six driving chips 11 may also be directly electrically connected through bonding wires.

In some embodiments, the number of driving chips 11 is one, and the number of light-emitting chip groups 12 is at least two. The two light-emitting chip groups 12 are connected to the driving chip 11 in series, so that the driving chip 11 can control light emission of the light-emitting chips connected in series.

In some embodiments, the blue chips of the plurality of light-emitting chips are connected in series to form a blue light-emitting group, the green chips of the plurality of light-emitting chips are connected in series to form a green light-emitting group, the red chips of the plurality of light-emitting chips are connected in series to form a red light-emitting group. The blue light-emitting group, the green light-emitting group and the red light-emitting group are arranged in parallel.

In some embodiments, the number of light-emitting chip groups 12 is six. The six blue chips 122 are connected in series, the six green chips 123 of the light-emitting chips are connected in series, the six red chips 121 of the light-emitting chips are connected in series. And, the six blue chips 122, the six green chips 123, and the six red chips 121 are arranged in parallel.

In some embodiments, the conductive pins 20 further include at least one transition pin 25. The transition pin 25 has a transition die-bonding portion 251. The transition die-bonding portion 251 is disposed between at least two adjacent die-bonding portions of the first die-bonding portion 211, the second die-bonding portion 221, the third die-bonding portion 231, and the fourth die-bonding portion 241. So that at least one of the first die-bonding portion 211, the second die-bonding portion 221, the third die-bonding portion 231, and the fourth die-bonding portion 241 can be electrically connected to the driving chip 11 and/or the light-emitting chip groups 12 through the transition die-bonding portion 251.

In some embodiments, a protection device is connected between the transition pin 25 and the power pin 22 to protect devices. The protection device may be a resistor and/or a diode, and can perform voltage division and current limiting to protect devices including the driving chip 11 and the light-emitting chip groups 12.

In some embodiments, at least some of the light-emitting chip groups 12 are disposed on the transition carrier and the signal input pin 23, and the remaining part of the light-emitting chip groups 12 are disposed on the power pin 22 and electrically connected to the power pin 22, so that the light-emitting chip groups 12 are arranged on the insulating base 30 at equal intervals.

In some embodiments, the second die-bonding portion 221 extends from the power pin 22 and then vertically extends toward one side of the insulating base 30 to form a fourth extending portion 2212. The fourth extending portion 2212 extends toward the other side of the insulating base 30 to form a fifth extending portion 2213. The fifth extending portion 2213 is parallel to the fourth extending portion 2212. The driving chip 11 is disposed at a junction between the fourth extending portion 2212 and the fifth extending portion 2213. At least some of the light-emitting chip groups 12 are disposed on the fifth extending portion 2213.

In some embodiments, the conductive pins 20 further include three transition pins 25. Each transition pin 25 has a transition die-bonding portion 251. The three transition die-bonding portions 251 are disposed on the insulating base 30 at intervals. The driving chip 11 is correspondingly connected to the blue chip 122, the green chip 123, and the red chip 121 through three transition die-bonding portions 251.

In some embodiments, the transition pins 25 include a first transition pin 25, a second transition pin 25, and a third transition pin 25. The first transition pin 25 has a first transition die-bonding portion 2511. The second transition pin 25 has a second transition die-bonding portion 2512. The third transition pin 25 has a third transition die-bonding portion 2513. The first transition die-bonding portion 2511 is disposed between the fifth extending portion 2213 and the fourth extending portion 2212. The second transition die-bonding portion 2512 is disposed between the fifth extending portion 2213 and the third transition die-bonding portion 2513. The third transition die-bonding portion 2513 is disposed adjacent to the third die-bonding portion 231.

In some embodiments, one of the blue chip 122 and the green chip 123 is disposed on one transition die-bonding portion 251, the other of the blue chip 122 and the green chip 123 is disposed on another transition die-bonding portion 251, and the red chip 121 is disposed on the fifth extending portion 2213 and connected to the driving chip 11 through the last transition die-bonding portion 251.

In some embodiments, the blue chip 122 is disposed on the first transition die-bonding portion 2511 and electrically connected to the fifth extending portion 2213. The green chip 123 is disposed on the third transition die-bonding portion 2513 and electrically connected to the fifth extending portion 2213. The red chip 121 is disposed on the fifth extending portion 2213 and electrically connected to the fifth extending portion 2213. The blue chip 122 is connected to the driving chip 11 through the first transition die-bonding portion 2511. The green chip 123 is connected to the driving chip 11 through the third transition die-bonding portion 2513. The red chip 121 is connected to the driving chip 11 through the second transition die-bonding portion 2512.

In some embodiments, the number of light-emitting chip groups 12 is two. Two blue chips 122 are disposed at two ends of one transition die-bonding portion 251. Two green chips 123 are disposed on another transition die-bonding portion 251. Two red chips 121 are disposed at two ends of the fifth extending portion 2213.

In some embodiments, the blue chips 122 are disposed at two ends of the first transition die-bonding portion 2511 and electrically connected to the fifth extending portion 2213. The green chips 123 are disposed at two ends of the third transition die-bonding portion 2513 and electrically connected to the fifth extending portion 2213. The red chips 121 are disposed at two ends of the fifth extending portion 2213 and electrically connected to the fifth extending portion 2213. The blue chip 122 is connected to the driving chip 11 through the first transition die-bonding portion 2511. The green chip 123 is connected to the driving chip 11 through the third transition die-bonding portion 2513. The red chip 121 is connected to the driving chip 11 through the second transition die-bonding portion 2512.

In some embodiments, the number of light-emitting chip groups 12 is at least three. At least three blue chips 122 are arranged at equal intervals in a length direction of one transition die-bonding portion 251. At least three green chips 123 are arranged at equal intervals in a length direction of another transition die-bonding portion 251. At least three red chips 121 are arranged at equal intervals in a length direction of the fourth extending portion 2212.

In some embodiments, the number of light-emitting chip groups 12 is six. Six blue chips 122 are arranged at equal intervals in the length direction of the first transition die-bonding portion 2511 and electrically connected to the fifth extending portion 2213. Six green chips 123 are arranged at equal intervals in the length direction of the third transition die-bonding portion 2513 and electrically connected to the fifth extending portion 2213. Six red chips 121 are arranged at equal intervals in the length direction of the fifth extending portion 2213 and electrically connected to the fifth extending portion 2213. The blue chip 122 is connected to the driving chip 11 through the first transition die-bonding portion 2511. The green chip 123 is connected to the driving chip 11 through the third transition die-bonding portion 2513. The red chip 121 is connected to the driving chip 11 through the second transition die-bonding portion 2512.

In the description of the present application, it should be noted that the terms “mounted”, “connected”, and “connected” should be understood broadly. For example, the connection may be a fixed connection, a detachable connection, or an integrated connection; it may be a mechanical connection or an electrical connection; it may be a direct connection or an indirect connection through an intermediate medium; it may be communication between interiors of two components or interaction between two components. A person of ordinary skill in the art may understand the meanings of the foregoing terms in the present application according to the situations.

In the present application, a first feature “on” or “under” a second feature may include direct contact between the first and second features, or may include contact between the first and second features not directly but through another feature therebetween. In addition, the first feature “on”, “above”, and “over” the second feature includes that the first feature is directly above and obliquely above the second feature, or simply means that a horizontal height of the first feature is higher than that of the second feature. The first feature “under”, “below”, and “beneath” the second feature includes that the first feature is directly below and obliquely below the second feature, or simply means that the horizontal height of the first feature is lower than that of the second feature.

The foregoing disclosure provides many different embodiments or examples for implementing different structures of the present application. To simplify the present application, the foregoing describes components and settings of examples. Of course, they are merely examples and are not intended to limit the present application. In addition, the present application may repeat reference numbers and/or reference letters in different examples. Such repetition is for the purpose of simplicity and clarity and does not indicate a relationship between various embodiments and/or settings discussed. In addition, the present application provides examples of various processes and materials, but a person of ordinary skill in the art may recognize application of other processes and/or use of other materials.

In the description of this specification, descriptions with reference to terms “one embodiment”, “some embodiments”, “schematic embodiments”, “examples”, “specific examples”, or “some examples” mean that features, structures, materials, or characteristics described in connection with the embodiment or example are included in at least one embodiment or example of the present application. In this specification, schematic expressions of the foregoing terms do not necessarily refer to the same embodiment or example. Moreover, the features, structures, materials, or characteristics described may be combined in any one or more embodiments or examples in a suitable manner.

What is claimed is:

1. An LED light strip structure, comprising:
an encapsulating body, end caps, and a light strip having a plurality of LEDs arranged at equal intervals; the encapsulating body covering an outer side of the light strip and extending in a length direction of the light strip, two ends of the light strip being respectively provided with an input end and an output end; the end caps being disposed at two ends of the encapsulating body, the end caps exerting a damping force to the input end and the output end to prevent the input end and the output end from sliding relative to the light strip;
wherein the encapsulating body at least comprises a light-transmissive encapsulant and a light-blocking encapsulant; the light strip has a light-emitting surface of the light strip, a backlight surface of the light strip, and two side surfaces of the light strip; the light-blocking encapsulant wraps outer sides of the two side surfaces of the light strip and extends in the length direction of the light strip, and the light-transmissive encapsulant is disposed on the light-emitting surface of the light strip and/or the backlight surface of the light strip.

2. The light strip structure according to claim 1, wherein the plurality of LEDs are arranged on the light strip at equal intervals, the light-blocking encapsulant is integrally formed with the light strip, a first long groove is formed at a light-emitting surface of the light strip, and the light-transmissive encapsulant is disposed in the first long groove, light emitted by the LEDs is emitted from the light-transmissive encapsulant in the first long groove.

3. The light strip structure according to claim 2, wherein a second long groove is formed in the light-blocking encapsulant at the backlight surface of the light strip, and the light-transmissive encapsulant is disposed in the second long groove, light strip information on the backlight surface of the light strip is displayed through the light-transmissive encapsulant.

4. The light strip structure according to claim 1, wherein each LED comprises a light-emitting assembly, an insulating base, an encapsulating compound, and a plurality of conductive pins; the plurality of conductive pins are disposed on the insulating base, the light-emitting assembly is disposed on the conductive pins and electrically connected to the conductive pins, and the encapsulating compound encloses the light-emitting assembly;
wherein the light-emitting assembly comprises at least one driving chip and a plurality of light-emitting chip groups combined in parallel or in series; the plurality of light-emitting chip groups are arranged sequentially in a layout direction of the insulating base, the at least one driving chip is electrically connected to the plurality of light-emitting chip groups, and a spacing between two adjacent light-emitting chip groups corresponds to a spacing between two adjacent LEDs.

5. The light strip structure according to claim 4, wherein each light-emitting chip group comprises a blue chip, a green chip, and a red chip; and at least one driving chip is electrically connected to the blue chip, the green chip, and the red chip to drive the blue chip, the green chip, and the red chip to emit light.

6. The light strip structure according to claim 5, wherein the insulating base has a first end surface; the conductive pins have die-bonding portions formed on the first end surface; and the driving chip, the blue chip, the green chip, and the red chip are disposed on the die-bonding portions and electrically connected to the die-bonding portions.

7. The light strip structure according to claim 5, wherein the conductive pins comprise a power pin and a ground pin; the driving chip is electrically connected to the power pin and the ground pin; the blue chip, the green chip, and the red chip are electrically connected to the power pin and the driving chip; and the blue chip, the green chip, and the red chip are arranged on the insulating base at equal intervals.

8. The light strip structure according to claim 7, wherein the driving chip is disposed on the ground pin, and the light-emitting chip groups are disposed on the power pin.

9. The light strip structure according to claim 7, wherein the conductive pins further comprise a signal input pin and a signal output pin;
the signal input pin and the signal output pin are electrically connected to a signal input end and a signal output end of the driving chip respectively; or a signal input end of one driving chip is electrically connected to a signal output end of an adjacent driving chip, the signal input pin is electrically connected to the signal input end of the driving chip on one side of the insulating base, and the signal output pin is electrically connected to the signal output end of the driving chip on the other side of the insulating base.

10. The light strip structure according to claim 9, wherein the number of the driving chips is at least two, the number of the light-emitting chip groups is at least two; the at least two light-emitting chip groups are correspondingly connected to the at least two driving chips and combined in parallel; and each driving chip correspondingly controls the light emission of each light-emitting chip group connected thereto.

11. The light strip structure according to claim 9, wherein the number of the driving chips is at least two, the number of the light-emitting chip groups is at least two; the at least two light-emitting chip groups are correspondingly connected to the at least two driving chips and combined in parallel; and the blue chip, the green chip, and the red chip on each light-emitting chip group are connected to the driving chip in series.

12. The light strip structure according to claim 9, wherein the number of the driving chips is one, the number of the light-emitting chip groups is at least two, and the at least two light-emitting chip groups are connected to the driving chip in series, the driving chip controls the light emission of the light-emitting chips connected in series.

13. The light strip structure according to claim 12, wherein the blue chips of the plurality of light-emitting chips are connected in series, the green chips of the plurality of light-emitting chips are connected in series, the red chips of the plurality of light-emitting chips are connected in series; and the blue chips, the green chips, and the red chips are arranged in parallel.

14. The light strip structure according to claim 4, wherein the conductive pins further comprise soldering portions, and the soldering portions are formed on end surfaces of the insulating base other than the first end surface.

15. The light strip structure according to claim 14, wherein a via structure is provided in a partial region of the soldering portions, and the via structure accommodates a soldering material.

16. The light strip structure according to claim 6, wherein the conductive pins further comprise at least one transition pin, the transition pin has a transition die-bonding portion, the transition die-bonding portion is disposed between two adjacent die-bonding portions, and at least some of the light-emitting chip groups are disposed on the transition die-bonding portion.

17. The light strip structure according to claim 16, wherein the number of the light-emitting chip groups is at least three, at least three blue chips are arranged at equal intervals in a length direction of one transition die-bonding portion, at least three green chips are arranged at equal intervals in a length direction of another transition die-bonding portion, and at least three red chips are arranged at equal intervals in a length direction of a fourth extending portion.

18. The light strip structure according to claim 16, wherein a protection device is connected between the transition pin and the power pin.

19. The light strip structure according to claim 1, wherein the light-blocking encapsulant and the light-transmissive encapsulant are made of a silica gel material or a PU material.

20. The light strip structure according to claim 19, wherein the light strip structure is curved.
